(19) United States
(12) Patent Application Publication
(10) Pub. No.: US 2004/0227252 A1
(43) Pub. Date: Nov. 18, 2004

(54) Flip chip package with reinforced bumps

(75) Inventor: Sung-Fei Wang, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/809,384

(22) Filed: Mar. 26, 2004

(30) Foreign Application Priority Data
Apr. 5, 2003 (TW) 092109531

(51) Int. Cl. H01L 23/52

(52) U.S. Cl. 257/778; 257/786; 257/737

(57) ABSTRACT

A flip chip package comprises a substrate, a chip, a plurality of electrically conductive bumps and reinforced bumps. The chip has an active surface having a central area and a peripheral area surrounding the central region. The electrically conductive bumps are disposed at the peripheral region of the chip to electrically connect to the substrate. In addition, the reinforced bumps are disposed at the central area of the chip. In such manner, it can enhance the connection between the chip and the substrate.

### BACKGROUND OF THE INVENTION

1. Field of Invention

This invention relates to a flip chip package. More particularly, the present invention is related to a flip chip package with reinforced bumps therein, which are interposed between the chip and the substrate. In such a manner, the reinforced bumps connecting the substrate and the chip will enhance the connection between the substrate and the chip.

2. Related Art

Recently, integrated circuits packaging technology is becoming a limiting factor for the development in packaged integrated circuits devices of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, flip chip packages, as shown in FIG. 1, including a substrate 110, a chip 120 and bumps 130 and 132, are commonly used in said assembly packages and electronic devices. Therein, said Flip Chip Interconnection Technology means a chip 120 having bumps 130 and 132 mounted on the active surface 122 thereof is disposed above the substrate 110 and mounted to the upper surface 112 of the substrate 110 through said bumps 130 and 132 so as to transmit the electrical signals of the chip 110 to external electronic device through the bumps 130 and 132 and the circuited layers (not shown) provided in the substrate 110. Accordingly, the size of said assembly package in a flip-chip type is reduced and the transmission path of the electrical signals is shortened. Namely, the signal delay is reduced and the electrical performance of said assembly package in a flip-chip type is enhanced.

As mentioned above, the chip 120 is electrically connected to the substrate 110 through electrically conductive bumps 130 and 132. However, the coefficient of thermal expansion of the substrate 110 is about 16*10⁻⁶ ppm/° C. and the coefficient of thermal expansion of the chip is about 4*10⁻⁶ ppm/° C. Accordingly, the coefficient of thermal expansion of the chip 120 is much smaller than that of the substrate 110 and the bumps 130 and 132, for example solder bumps and gold bumps, connecting the chip 120 and the substrate 110 are usually damaged due to the CTE mismatch of the substrate 110 with the chip 120. Although there is an underfill 140 interposed between the substrate 110 and the active surface 122 of the chip 120 so as to fill into the space between the substrate 110 and the chip 120 and lower the stress at the bumps 130 and 132, the bumps 130 and 132 are still damaged due to the much difference of the coefficient of thermal expansion of the substrate 110 from that of the chip 120. In addition, when the size of the chip 120 is much larger than usual one for special design and the distance D between the inside bumps 130 and 132 attached to said chip 120 is much larger than usual design, for example the size of the chip 120 is 715 mm ×715 mm, the bumps 130 and 132 located, close to the center, at the central area of the active surface 122 of the chip 120 will be easily damaged than others disposed at the outer area surrounding the central area.

Therefore, providing another flip chip assembly package to solve the mentioned-above disadvantages is the most important task in this invention.

### SUMMARY OF THE INVENTION

In view of the above-mentioned problems, an objective of this invention is to provide a flip chip package having reinforced bumps, wherein the bumps of the flip chip package is able to be prevented from being damaged because said reinforced bumps interposed between the chip and the substrate can enhance the bonding strength of the chip to the substrate.

To achieve the above-mentioned objective, a flip chip package is provided, wherein the flip chip package mainly comprises a substrate, a chip, reinforced bumps, and a plurality of electrically conductive bumps. Therein, the chip has an active surface having a central area and a peripheral area surrounding the central area. The chip is flipped over and the active surface of the chip is mounted on and electrically connected to the upper surface of the substrate through the electrical conductive bumps located at the peripheral area. Moreover, the reinforced bumps are disposed at the central area of the active surface of the chip and attached to the substrate so as to enhance the connection between the chip and the substrate.

In summary, this invention is related to a flip chip package utilizing a reinforced bump formed between and further connecting the chip and the substrate to enhance the bonding strength of the chip to the substrate. In such a manner, it can lower the stress at the electrically conductive bumps so as to prevent said electrically conductive bumps from being easily damaged and to enhance the reliability of said flip chip package.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional flip chip package;

FIG. 2 is a cross-sectional view of a flip chip package according to the preferred embodiment;

FIG. 3 is a top view of the upper surface of the substrate according to the preferred embodiment as shown in FIG. 2; and

FIG. 4 is a top view of the active surface of the chip according to the preferred embodiment as shown in FIG. 2.

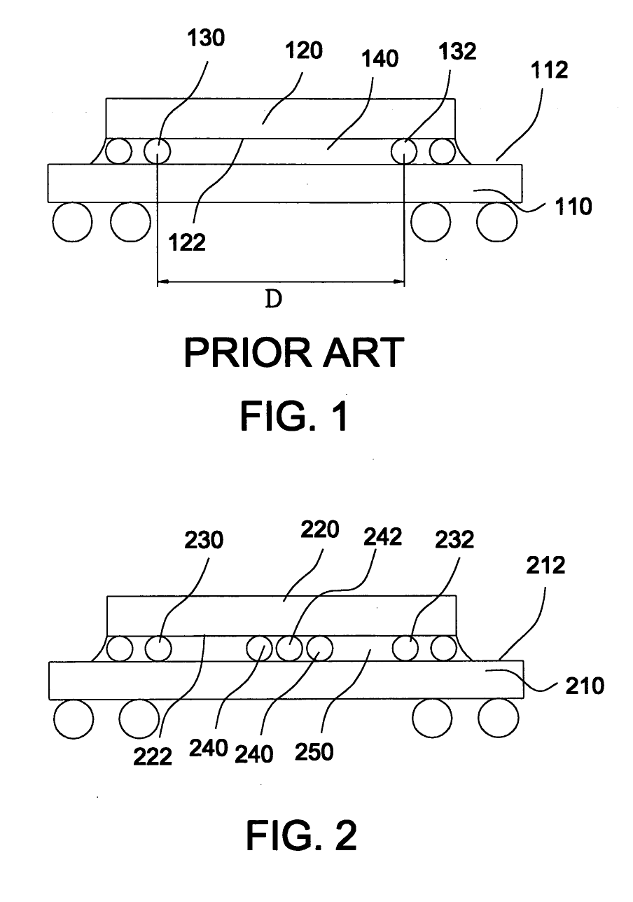

### DETAILED DESCRIPTION OF THE INVENTION

The flip chip package according to the preferred embodiment of this invention will be described herein below with reference to the accompanying drawings, wherein the same reference numbers refer to the same elements.

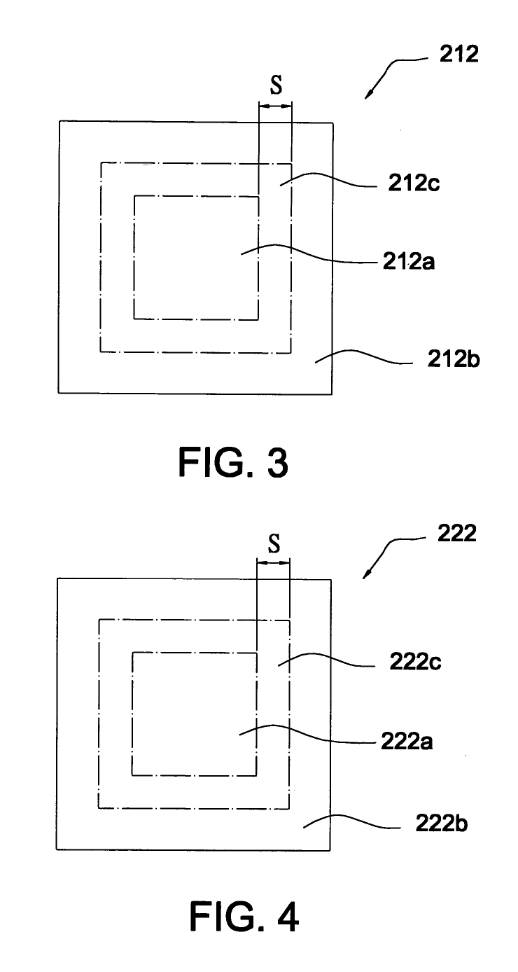

In accordance with a preferred embodiment as shown in FIG. 2, FIG. 3 and FIG. 4, there is provided a flip chip package. The flip chip package mainly comprises a substrate 210, a chip 220, a plurality of electrically conductive bumps 230 and 232, and a plurality of reinforced bumps 240 and 242. The substrate 210 has an upper surface 212, as shown in FIG. 3, having a first central area 212a, for example a rectangular area, and a first peripheral area 212b surrounding, for example a ring-like area, the first central area 212a. Similarly, the chip 220 also has an active surface 222, as shown in FIG. 4, with a second central area 222a and a second peripheral area 222b corresponding to the first central area 212a and first peripheral area 212b respectively. The chip 220 is attached to the substrate 210 through the electrically conductive bumps 230 and 232, for example solder bumps and lead-free bumps, interposed between the first peripheral area 212b and the second peripheral area 222b and the reinforced bumps 240 and 242, for example gold bumps, epoxy bumps and plastic bumps with coated metal layers thereon, interposed between the first central area 212a and the second central area 222a; and the bonding strength of the substrate 210 to the chip 220 are enhanced due to the reinforced bumps 240 and 242.

In general designs for a larger chip, the bonding pads of the chip are distributed at the peripheral of the active surface of the chip. Accordingly, the reinforced bumps 240 and 242 are usually located at the central area 222a of the active surface 222 of the chip 220. When the size of the chip 220 becomes larger and larger, the size of the area not having electrically conductive bumps 230 and 232 thereon also becomes larger and larger. However, usually, the electrically conductive bumps 230 and 232, interposed between the chip 220 and the substrate 210, located close to the first central area 212a of the substrate 210 or the second central area 222a of the chip 220, are more easily damaged than others located at the area far way from the first central area. Thus, the bumps 230 and 232 located at a first intermediate area 212c between the first central area 212a and the first peripheral area 222a are not easily damaged. Namely, the bumps 230 located at the second intermediate area 222c between the second central area 222a and the second peripheral area 222b are not easily damaged. In such a manner, when the width “S”, the distance between the outermost reinforced bump 240 and the innermost electrically conductive bump 230, of the second intermediate area 222c is substantially equal to or greater than the double of the width of the electrically conductive bump 230 or the reinforced bump 240, it is unnecessary to provide reinforced bumps 240 at the second intermediate area 222c. Moreover, when the electrically conductive bump 230 and the reinforced bump 240 are shaped into sphere and the width “S” of the second intermediate area 222c is greater than or substantially equal to the double of the diameter of the electrically conductive bump 230 or the reinforced bump 240, there are also not provided reinforced bumps 240 at the second intermediate area 222c. Similarly, there is further an underfill 250 disposed between the substrate 210 and the chip 220.

As mentioned above, the first central area 212a and the second central area 212b are rectangular so that the reinforced bumps 240 and 242 may arrange as a matrix at the first central area 212a. In addition, the reinforced bumps 240 and 242 connecting the chip 220 and the substrate 210 are made of metal so the reinforced bumps 240 and 242 can be taken as thermal bumps for enhancing thermal performance of the package. Furthermore, when the reinforced bump 240 is formed in a ring-like bump located at the first central area 212a, the bonding strength of the chip 220 to the substrate 210 will be further enhanced.

Although the invention has been described in considerable detail with reference to certain preferred embodiments, it will be appreciated and understood that various changes and modifications may be made without departing from the spirit and scope of the invention as defined in the appended claims.

What is claimed is:

1. A flip chip package, comprising:
a substrate having an upper surface and a lower surface, wherein the substrate has a first central area and a first peripheral area encompassing the first central area;
a chip having an active surface, wherein the active surface has a second central area and a second peripheral area encompassing the second central area;
a plurality of electrically conductive bumps connecting the first peripheral area and the second peripheral area; and
a plurality of reinforced bumps interposed between the chip and the substrate, wherein the reinforced bump connects the first central area and the second central area.

2. The flip chip package of claim 1, wherein the first central area is rectangular.

3. The flip chip package of claim 1, wherein the first peripheral area is ring-like.

4. The flip chip package of claim 1, wherein the substrate further comprises a first intermediate area between the first central area and the first peripheral area, and the first intermediate area is ring-like.

5. The flip chip package of claim 1, wherein the electrically conductive bumps comprises an innermost electrically conductive bump close to a center of the first central area and the reinforced bumps comprise an outermost reinforced bump far way from the center of the first central area.

6. The flip chip package of claim 4, wherein the first intermediate area has a width at least larger than the double of a width of the electrically conductive bump.

7. The flip chip package of claim 5, wherein a distance between the innermost electrically conductive bump and the outermost reinforced bump is at least larger than the double of a width of the reinforced bump.

8. The flip chip package of claim 4, wherein the electrically conductive bump is a sphere and the first intermediate area has a width is at least larger than a diameter of the electrically conductive bump.

9. The flip chip package of claim 5, wherein one of the reinforced bumps is a sphere and a distance between the innermost electrically conductive bump and the outermost reinforced bump is at least larger than the double of a diameter of the reinforced bump.

10. The flip chip package of claim 1, further comprising an underfill disposed between the chip and the substrate and covering the electrically conductive bumps.

11. The flip chip package of claim 1, further comprising an underfill disposed between the chip and the substrate and covering the reinforced bumps.

12. The flip chip package of claim 1, wherein the reinforced bumps comprises metal bumps.

13. The flip chip package of claim 1, wherein one of the reinforced bumps is a thermally conductive bump.

14. The flip chip package of claim 1, further comprising a solder ball formed on the lower surface of the substrate.

15. The flip chip package of claim 4, wherein the electrically conductive bump is a sphere and the first intermediate area has a width is substantially equal to the double of a diameter of the electrically conductive bump.

16. The flip chip package of claim 5, wherein one of the reinforced bumps is a sphere and a distance between the innermost electrically conductive bump and the outermost reinforced bump is substantially equal to the double of a diameter of the reinforced bump.

17. The flip chip package of claim 1, wherein one of the reinforced bumps is a ring-like bump.

18. The flip chip package of claim 1, wherein the reinforced bumps are made of epoxy.
